(19) United States
(12) Patent Application Publication
(10) Pub. No.: US 2023/0091623 A1
(43) Pub. Date: Mar. 23, 2023

(54) DEFECT INSPECTING METHOD AND SYSTEM PERFORMING THE SAME

(71) Applicant: NANYA TECHNOLOGY CORPORATION, New Taipei City (TW)

(72) Inventors: CHIH-LEI CHANG, TAOYUAN CITY (TW); CHUN-YU LIN, TAOYUAN CITY (TW); LI-PING YU, TAOYUAN CITY (TW); SHAO-HSUAN CHANG, TAOYUAN CITY (TW)

(21) Appl. No.: 17/482,946

(22) Filed: Sep. 23, 2021

(51) Int. Cl. G11C 29/38; G11C 11/4072; G11C 11/4096; G11C 11/408

(52) U.S. Cl. CPC G11C 29/38; G11C 11/4072; G11C 11/4096; G11C 11/4085; G11C 11/4087

(57) ABSTRACT

The present disclosure provides a defect inspecting method and a defect inspecting system configured to inspect a memory device. The defect inspecting method includes the operations of: resetting the memory device from a power on state; initializing the memory device; performing a plurality of write operations to a memory cell array of the memory device according to a test pattern; performing a plurality of read operations to the memory cell array of the memory cell to generate a readout pattern; and determining whether a defect existed in the memory device according to the readout pattern.

### TECHNICAL FIELD

The present disclosure relates to an inspecting method and system, and more particularly, to a defect inspecting method and a system performing the same.

### DISCUSSION OF THE BACKGROUND

In dynamic random access memory (DRAM) process, the process residual affects the electrical property of the DRAM. When the electrical property of the DRAM is differed from the desired value, the read operation and/or write operation cannot be performed properly. Therefore, detecting whether the electrical property of the DRAM is affected by the process becomes an important issue in this field.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a defect inspecting method configured to inspect a memory device. The defect inspecting method includes the operations of: resetting the memory device from a power on state; initializing the memory device; performing a plurality of write operations to a memory cell array of the memory device according to a test pattern; performing a plurality of read operations to the memory cell array of the memory cell to generate a readout pattern; and determining whether a defect existed in the memory device according to the readout pattern.

In some embodiments, resetting the memory device from the power on state includes the operations of: powering off the memory device; discharging the memory device, wherein the operation of discharging the memory device is performed lasting a predetermined duration; and powering on the memory device after the operation of discharging the memory device.

In some embodiments, the predetermined duration is longer than 1 second.

In some embodiments, discharging the memory device includes the operations of: discharging a word line driver array of the memory device; and discharging a row decoder of the memory device.

In some embodiments, the test pattern indicates a plurality of first logic states being written in a plurality of memory cells of the memory array, respectively, and the readout pattern indicates a plurality of second logic states read from the plurality of memory cells of the memory array, respectively.

In some embodiments, determining whether the defect existed in the memory device according to the readout pattern includes the operation of: comparing the plurality of the first logic states to the plurality of the second logic states. When at least one of the plurality of second logic states is different from the corresponded first logic state, the defect is determined existing in the memory device.

In some embodiments, the memory device includes a row decoder and a word line driver array coupled to the row decoder through a main word line. The operation of determining whether the defect existed in the memory device according to the readout pattern is configured to detect whether the defect existed on the main word line

In some embodiments, the word line driver array includes a plurality of word line drivers. At least one of the word line drivers includes a first pull-down transistor, a second pull-down transistor, and a pull-up transistor. The first pull-down transistor has a first gate terminal, a first source/drain (S/D) terminal, and a second S/D terminal. The second pull-down transistor has a second gate terminal, a third S/D terminal, and a fourth S/D terminal. The pull-up transistor has a third gate terminal, a fifth S/D terminal, and a sixth S/D terminal. The first gate terminal and the third gate terminal are configured to receive a main word line signal, the second gate terminal is configured to receive a reset signal, the first S/D terminal, the third S/D terminal, and the sixth S/D terminal are coupled to a sub word line, the fifth S/D terminal is configured to receive a first voltage, and the second S/D terminal and the fourth S/D terminal are configured to receive a second voltage. The operation of determining whether the defect existed in the memory device according to the readout pattern is further configured to detect whether the defect existed between the sub word line and the first S/D terminal.

In some embodiments, the operation of determining whether the defect existed in the memory device according to the readout pattern is further configured to detect whether the defect existed between the sub word line and the third S/D terminal.

In some embodiments, the defect increases a resistance of the main word line.

Another aspect of the present disclosure provides a defect inspecting system. The defect inspecting system includes a test device configured to: reset the memory device from a power on state to the power on state through a power off state; perform a plurality of read operations to the plurality of memory cells to generate a readout pattern; and determine whether a defect existed in the memory device according to a readout pattern. The memory device is a Dynamic Random Access Memory (DRAM) device.

In some embodiments, the test device is further configured to: initialize the memory device; and perform a plurality of write operations to a plurality of memory cells of the memory device according to a test pattern.

In some embodiments, the test device determines whether the defect existed in the memory device according to the readout pattern by comparing the readout pattern to the test pattern, wherein the test pattern indicates a plurality of first logic states being written in the memory device, and the readout pattern indicates a plurality of second logic states read from the memory device. When at least one of the plurality of the second logic states is different from the corresponded first logic state, the test device determines the defect existed in the memory device.

In some embodiments, the test device resets the memory device by: powering off the memory device to the power off state; discharging the memory device for a predetermined duration in the power off state; and powering on the memory device to the power on state.

In some embodiments, the predetermined duration is longer than 1 second.

In some embodiments, the memory device includes a memory array, a row decoder, and a word line driver array. The memory array includes a plurality of memory cells. The row decoder is configured to provide a main word line signal through a main word line. The word line driver array is configured to receive the main word line signal, wherein the word line driver array includes a plurality of word line drivers, and at least one of the word line drivers is configured to generate a sub word line signal to the memory array. The test device is configured to discharge the main word line.

In some embodiments, the test device is configured to determine whether the defect existed on the main word line, wherein the defect is caused by an oxide residual.

In some embodiments, at least one of the word liner drivers includes a first pull-down transistor, a second pull-down transistor, and a pull-up transistor. The first pull-down transistor has a first gate terminal, a first source/drain (S/D) terminal, and a second S/D terminal. The second pull-down transistor has a second gate terminal, a third S/D terminal, and a fourth S/D terminal. The pull-up transistor has a third gate terminal, a fifth S/D terminal, and a sixth S/D terminal. The first gate terminal and the third gate terminal are configured to receive a main word line signal, the second gate terminal is configured to receive a reset signal, the firs S/D terminal, the third S/D terminal, and the sixth S/D terminal are coupled to a sub word line, the fifth S/D terminal is configured to receive a first voltage, and the second S/D terminal and the fourth S/D terminal are configured to receive a second voltage. The test device is configured to discharge the word line driver.

In some embodiments, the test device is configured to determine whether the defect existed between the sub word line and the first S/D terminal, and/or between the sub word line and the third S/D terminal.

In some embodiments, the test device is configured to tag the memory device as a fail device when the defect exists in the memory device.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures.

FIG. 1 is a schematic diagram of a defect inspecting system according to some embodiments of the present disclosure.

FIG. 2 is a schematic diagram of a memory device according to some embodiments of the present disclosure.

FIG. 3 is a schematic diagram of a memory cell array according to some embodiments of the present disclosure.

FIG. 4 is a schematic diagram of a memory cell array in a read operation according to some embodiments of the present disclosure.

FIG. 5 is a schematic diagram of a memory cell array in a read operation according to other embodiments of the present disclosure.

FIG. 6 is a schematic diagram of a memory cell array in a read operation according to alternative embodiments of the present disclosure.

FIG. 7 is a schematic diagram of a memory cell array in a read operation according to various embodiments of the present disclosure.

FIG. 8 is a schematic diagram of a word line driver according to some embodiments of the present disclosure.

FIG. 9 is a schematic diagram of a word line driver according to some embodiments of the present disclosure.

FIG. 10 is a schematic diagram of a word line driver according to other embodiments of the present disclosure.

FIG. 11 is a schematic diagram of a word line driver according to alternative embodiments of the present disclosure.

FIG. 12 is a schematic diagram of a word line driver according to various embodiments of the present disclosure.

FIG. 13 is a flow chart of a defect inspecting method according to some embodiments of the present disclosure.

FIG. 14 is a flow chart of an operation of the defect inspecting method according to some embodiments of the present disclosure.

FIG. 15 is a schematic diagram of a wave form of a supply power of the memory device according to some embodiments of the present disclosure.

FIG. 16 is a flow chart of an operation of the defect inspecting method according to some embodiments of the present disclosure.

FIG. 17 is a schematic diagram of a test pattern according to some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another element, component, region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limiting to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

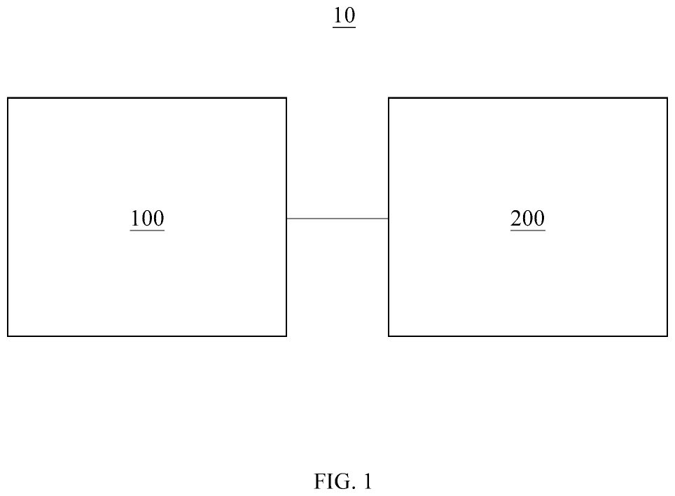

FIG. 1 is a schematic diagram of a defect inspecting system 10 according to some embodiments of the present disclosure. The defect inspecting system 10 includes a test device 100 configured to inspect a memory device 200. In some embodiments, the test device 100 is an automatic test equipment (ATE). In some embodiments, the memory device 200 is a dynamic random access memory (DRAM) device. However, the present disclosure is not limited thereto. The test device 100 is further configured to inspect other device.

The test device 100 is configured to inspect whether a defect existed in the memory device 200. When a defect exists in the memory device 200, the test device 100 is configured to tag the memory device 200 as a fail device. In some embodiments, the fail device is dropped out from the batch of the memory devices. When there is no defect existing in the memory device 200, the test device 100 is configured to tag the memory device 200 as a pass device.

In some embodiments, during manufacturing process of the memory device 200, an undesired particle existed in the memory device 200 may affect the electrical property of the memory device 200.

For example, the undesired particle can be an oxide residual remained from an oxide etching process, and the oxide residual increases an effective resistance of conductive trace there below. In this situation, the memory device 200 may have unsatisfied electrical property due to the oxide residual.

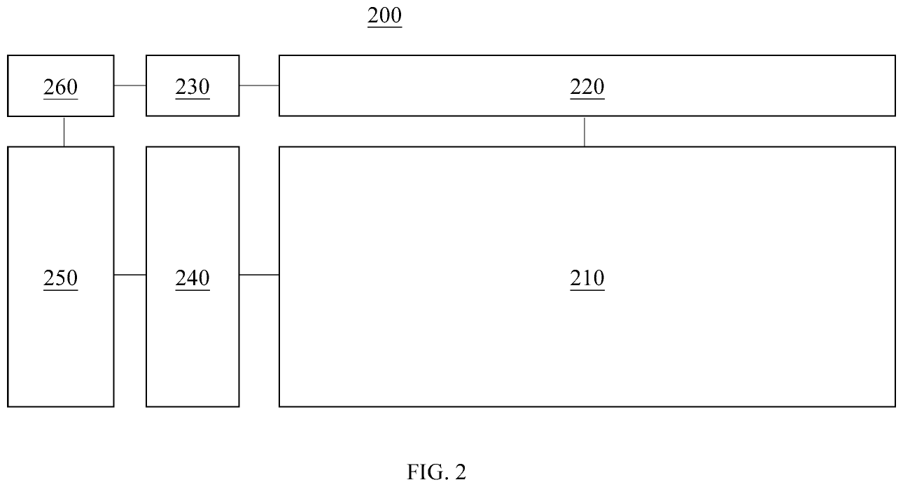

Reference is made to FIG. 2. FIG. 2 is a schematic diagram of the memory device 200 according to some embodiments of the present disclosure. The memory device 200 includes a memory cell array 210, a word line driver array 220, a row decoder 230, a bit line driver array 240, a column decoder 250, and a controller 260.

The row decoder 230 is coupled to the word line driver array 220. The column decoder 250 is coupled to the bit line driver array 240. The word line driver array 220 and the bit line driver array 240 are coupled to the memory cell array 210. The controller 260 is coupled to the row decoder 230 and the column decoder 250. In some embodiments, the controller 260, the row decoder 230, and the column decoder 250 are a single module.

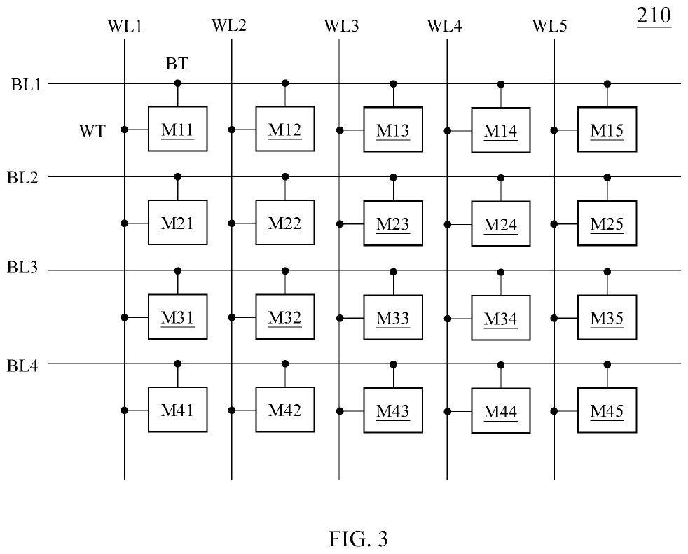

Reference is made to FIG. 3. FIG. 3 is a schematic diagram of the memory cell array 210 according to some embodiments of the present disclosure. The memory cell array 210 includes a plurality of memory cells denoted from M11 to Mij, in which i and j are integers and represent the memory cell Mij located at the ith row and jth column of the memory cell array 210. In FIG. 3, the memory cell array 210 has 5 rows and 4 columns. In other words, the memory cell array 210 is coupled to 5 word lines WL1-WL5, and coupled to 4 bit line BL1-BL4. It is noted that the numbers of the rows, columns, word lines, and bit lines are not limited thereto.

The memory cell Mij includes a word line terminal WT and a bit line terminal BT. The word line terminals WT of the memory cells M11-M41 are coupled to the word lines WL1; the word line terminals WT of the memory cells M12-M42 are coupled to the word lines WL2; the word line terminals WT of the memory cells M13-M43 are coupled to the word lines WL3; the word line terminals WT of the memory cells M14-M44 are coupled to the word lines WL4; and the word line terminals WT of the memory cells M15-M45 are coupled to the word lines WLS. The bit line terminals BT of the memory cells M11-M15 are coupled to the bit line BL1; the bit line terminals BT of the memory cells M21-M25 are coupled to the bit line BL2; the bit line terminals BT of the memory cells M31-M35 are coupled to the bit line BL3; and the bit line terminals BT of the memory cells M41-M45 are coupled to the bit line BL4.

In a read option of the memory device 200, only one of the word lines WL1-WL5 is activated, and the others are deactivated. For example, when the word line WL1 is asserted high (i.e., when a voltage on the word line WL1 has a logic level which activates the memory cells M11-M41), other word lines WL2-WL5 are asserted low (i.e., when the voltage on the word lines WL2-WL5 has a logic level which deactivates the memory cells Mij other than M11-M41). On the bit line BL1, because only the word line WL1 is activated, the bit line BL1 can only read the data stored in the memory cell M11. Similarly, the bit lines BL2-BL4 can only read the datas stores in the memory cell M21-M41, respectively.

In a write operation of the memory device 200, only one of the word lines WL1-WL5 is activated, and the others are deactivated. The bit lines BL1-BL4 provide charge to the memory cells Mij coupled to the word line which is asserted high, so as to make said memory cells Mij store the charge. For example, when the word line WL1 is asserted high, other word lines WL2-WL5 are asserted low. On the bit line BL1, because only the memory cell M11 is activated, the charge provided by the bit line BL1 can only be transmitted to the memory cell M11 to write the memory cell M11. Other memory cells M12-M15 on the bit line BL1 do not receive the provided charge. Similarly, the bit lines BL2-BL4 can only write the memory cell M21-M41 with the provided charge, respectively.

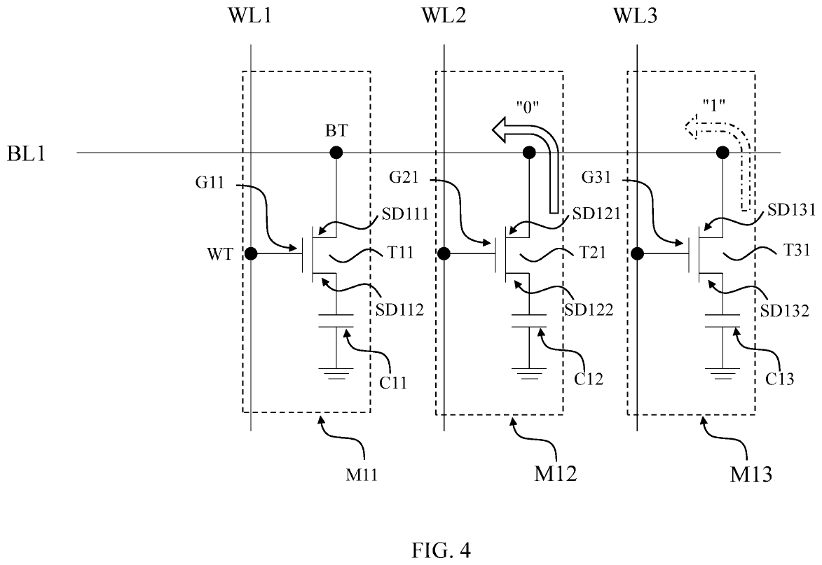

Reference is made to FIG. 4. FIG. 4 is a schematic diagram of the memory cell array 210 in a read operation according to some embodiments of the present disclosure. To facilitate understanding, only the bit line BL1, the word lines WL1-WL3, and the memory cell M11-M13 are illustrated in FIG. 4, and other components of the memory cell array 210 are omitted.

The memory cell Mij includes a transistor Tij and a capacitor Cij. In some embodiments, the transistors Tij are n-type metal-oxide-semiconductor (NMOS) transistors. As shown in FIG. 4, the memory cells M11-M13 includes the transistors T11-T13 and the capacitors C11-C13, respectively. The transistor Tij includes a gate terminal Gij, a source/drain (S/D) terminal SDij1, and an S/D terminal SDij2. In FIG. 4, the gate terminals G11-G13 are coupled to the word lines WL1-WL3, respectively; the S/D terminals SD111-SD131 are coupled to the bit line BL1; and the capacitors C11-C13 couple the S/D terminals SD112-SD132 to the ground, respectively.

In some embodiments, the word line WL2 is asserted high and the word lines WL1 and WL3 are asserted low in a read operation to read the memory cell M12. When the word line WL2 is asserted high, the voltage on the word line WL2 makes the transistor T12 be turned on. The charge (i.e., the data) stored in the memory cell M12 is then able to be transmitted to the bit line BL1 from the capacitor C12 through the transistor T12. Therefore, a sensing amplifier (not shown) coupled to the bit line BL1 can sense the charge so as to transform the charge to a logic state which represents the stored data.

In the memory cell Mij, the charge is accumulated at the capacitor Cij, and accumulated charge represents the logic state of the memory cell Mij. The logic state can have a logic high level or a logic low level, which is digital “1” or digital “0”.

Generally, the datas stored in the memory cells M11 and M13 cannot be read because the word line WL1 and WL3 are asserted low. However, when a defect exists to affect the electrical property of the word lines WL1 and WL3, the word lines WL1 and WL3 might not work properly. In some embodiments, when the word line WL2 is asserted high, the word line WL3 is not asserted low at a desired level, and the memory cell M13 is partially turned on. As the embodiment in FIG. 4, the charge stored in the memory cell M12 is read by the sense amplifier. Meanwhile, because the memory cell M13 is partially turned on, the charge accumulated at the capacitor C13 is also read by the sense amplifier. The above phenomenon is also referred to as charge sharing. When the charge sharing occurs, the sense amplifier senses the charge not only stored in the target memory cell M12 but also in the undesired memory cell M13. As the example in FIG. 4, the sense amplifier should sense the charge stored in the memory cell M12 and transform the charge to the digital “0”. However, when the charge (representing digital “1”) stored in the memory cell M13 is shared to the bit line BL1, the sense amplifier eventually senses the total charge from the memory cells M12 and M13. Therefore, the sense amplifier transforms the sensed charge to another logic state other than digital “0”.

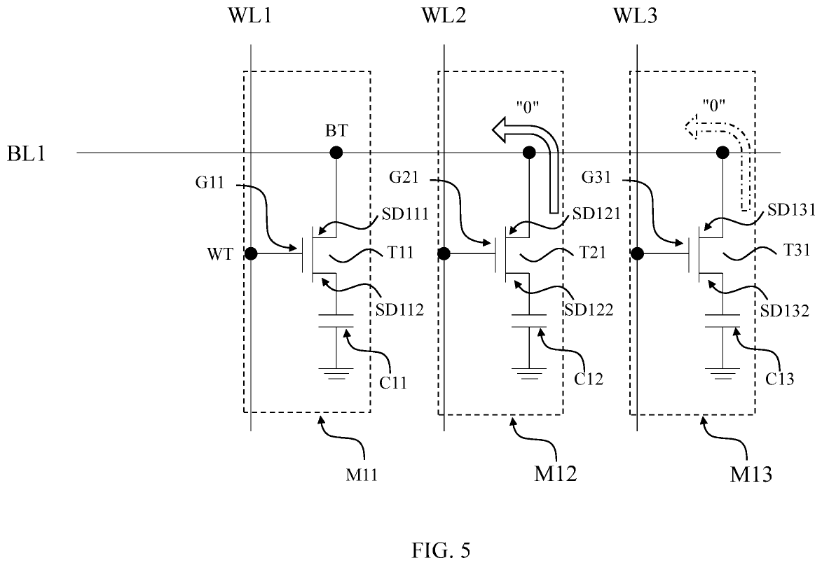

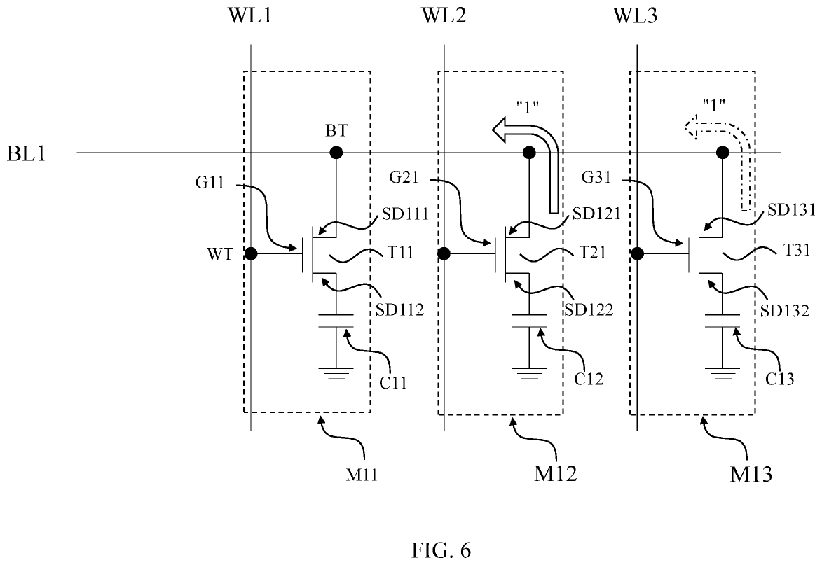

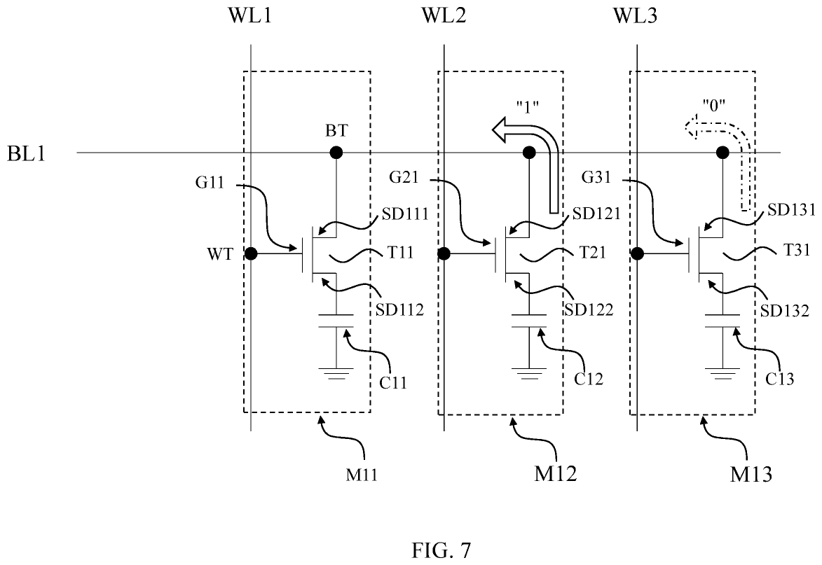

In some embodiments, the word line WL3 which partially turns on the memory cell M13 is also referred to as a floating word line. When the memory device 200 includes a floating word line, the data may be read incorrectly. In other embodiments, when the memory device 200 includes a floating word line, the data may still be read correctly. Please refer to FIG. 5, FIG. 6, and FIG. 7 for explanation.

FIG. 5 is a schematic diagram of the memory cell array 210 in a read operation according to other embodiments of the present disclosure. The memory cell array 210 shown in FIG. 5 is similar to the memory cell array 210 shown in FIG. 4. Compared to the memory cell array 210 in FIG. 4, the data stored in the memory cell M13 represents digital “0”.

In some embodiments, when the data represents digital “0”, the amount of charge accumulated in the capacitor C13 is substantially equal to 0. Under this condition, even if the word line WL3 is a floating word line, there is no charge to share to the bit line BL1. Therefore, when the word line WL2 turns on the memory cell M12 and the word line WL3 partially turns on the memory cell M13, the memory cell M13 does not contribute any charge to the charge sensed by the sense amplifier.

FIG. 6 is a schematic diagram of the memory cell array 210 in a read operation according to alternative embodiments of the present disclosure. The memory cell array 210 shown in FIG. 6 is similar to the memory cell array 210 shown in FIG. 4. Compared to the memory cell array 210 in FIG. 4, the data stored in the memory cell M12 represents digital “1”.

In some embodiments, when the data represents digital “1”, the amount of charge accumulated in the capacitor C12 is greater than a threshold. When any amount of charge greater than the threshold is sensed by the sense amplifier, the sense amplifier transforms the sensed charge to digital “1”. Under this condition, even if the word line WL3 is a floating word line and contributes the charge to be sensed, the sense amplifier still generates the digital “1”.

FIG. 7 is a schematic diagram of the memory cell array 210 in a read operation according to various embodiments of the present disclosure. The memory cell array 210 shown in FIG. 7 is similar to the memory cell array 210 shown in FIG. 4. Compared to the memory cell array 210 in FIG. 4, the data stored in the memory cell M12 represents digital “1”, and the data stored in the memory cell M13 represents digital “0”.

Under this condition, the word line WL3 is a floating word line. When the word line WL2 turns on the memory cell M12 and the word line WL3 partially turns on the memory cell M13, the charge stored in the memory cell M12 is shared to the memory cell M13 through the bit line BL1. Therefore, the charge sensed by the sense amplifier is decreased, and the data generated by the sense amplifier may not be the digital “1”.

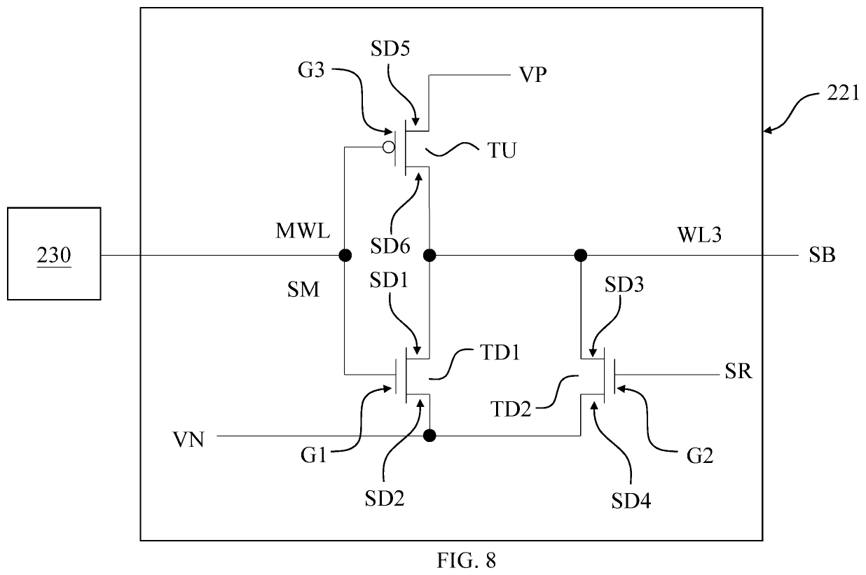

Reference is made to FIG. 8. FIG. 8 is a schematic diagram of a word line driver 221 according to some embodiments of the present disclosure. The word line driver array 220 includes a plurality of word line drivers 221, and the word line driver 221 is coupled to a word line. To facilitate understanding, only the word line driver 221 coupled to the word line WL3 is illustrated.

The word line driver 221 includes a pull-up transistor TU, a pull-down transistor TD1, and a pull-down transistor TD2. The pull-down transistor TD1 includes a gate terminal G1, an S/D terminal SD1, and an S/D terminal SD2. The pull-down transistor TD2 includes a gate terminal G2, an S/D terminal SD3, and an S/D terminal SD4. The pull-up transistor TU includes a gate terminal G3, an S/D terminal SD5, and an S/D terminal SD6.

The gate terminal G1 and the gate terminal G3 are coupled to the row decoder 230 through a main word line MWL, and configured to receive a main word line signal SM. The gate G2 is configured to receive a reset signal SR. The S/D terminal SD5 is configured to receive a first voltage VP. The S/D terminal SD2 and the S/D terminal SD4 are configured to receive a second voltage VN. The S/D terminal SD1, the S/D terminal SD3, and the S/D terminal SD6 are coupled to the word line WL3, and configured to generate a sub word line signal SB. In some embodiments, the word lines WL1-WL5 are also referred to as sub word lines.

As illustrated in FIG. 8, the pull-up transistor PU is a PMOS transistor, the pull-down transistor PD1 and the pull-down transistor PD2 are NMOS transistors. The first voltage VP is greater than the second voltage VN. When the word line WL3 has the first voltage VP thereon, the memory cells M13-M43 coupled to the word line WL3 are turned on. When the word line WL3 has the second voltage VN thereon, the memory cells M13-M43 coupled to the word line WL3 are turned off.

When the main word line signal SM and the reset signal SR have the voltage indicating digital “0”, the pull-up transistor TU is turned on, and the pull-down transistors TD1 and TD2 are turned off. The word line WL3 is pulled up to the first voltage VP and asserted high.

When the main word line signal SM and the reset signal SR have the voltage indicating digital “1”, the pull-up transistor TU is turned off, and the pull-down transistors TD1 and TD2 are turned on. The word line WL3 is pulled down to the second voltage VN and asserted low.

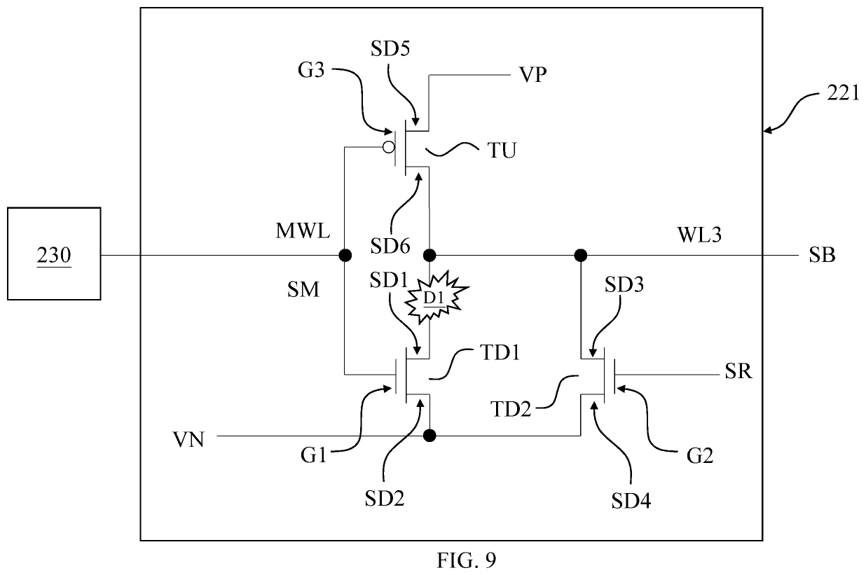

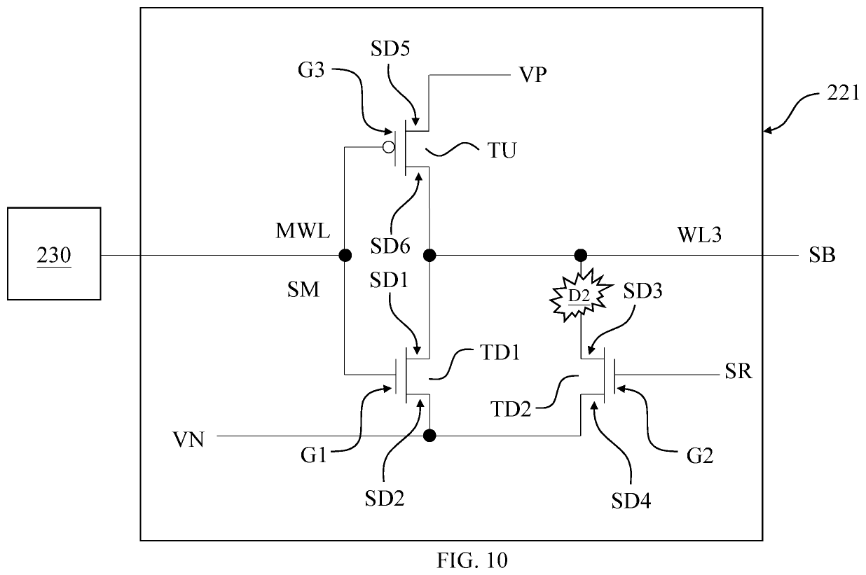

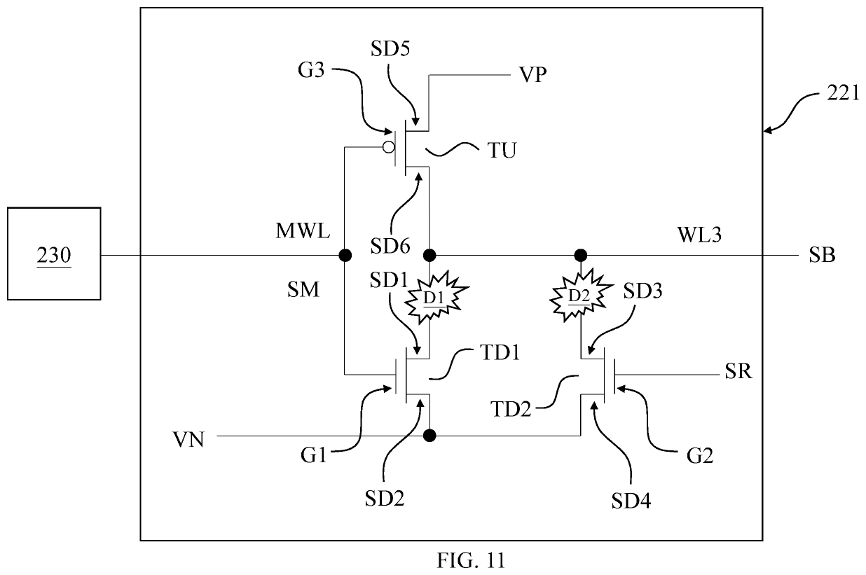

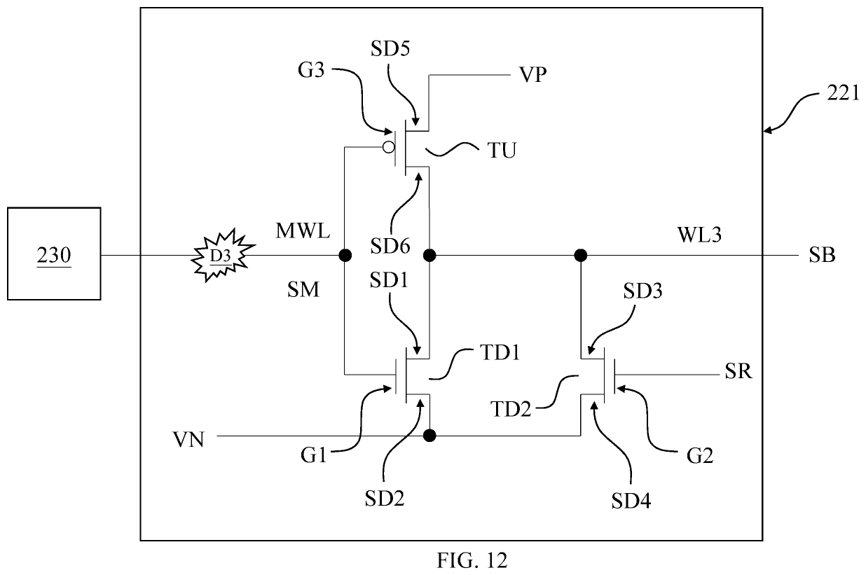

In some embodiments, a defect exists in the word driver 211. Please refer to FIG. 9, FIG. 10, FIG. 11, and FIG. 12.

FIG. 9 is a schematic diagram of the word line driver 211 according to some embodiments of the present disclosure. As illustrated in FIG. 9, a defect D1 is located on a conductive trace between the S/D terminal SD1 and the word line WL3.

In some embodiments, the defect D1 is an oxide residual which increases the resistance of the conductive trace between the S/D terminal SD1 and the word line WL3.

When a read operation is performed to assert the word line WL2 high, the word line WL3 is asserted low. The main word line signal SM and the reset signal SR are set to the voltage representing digital “1” to turn on the pull-down transistors TD1 and TD2, so as to pull the word line WL3 down to the second voltage VN. However, the resistance of the conductive trace between the S/D terminal SD1 and the word line WL3 increases due to the defect D1, the voltage on the word line WL3 is pulled down to approach but not be equal to the second voltage VN.

In this condition, the pull-down transistor TD2 can still pull the word line WL3 down to the second voltage VN. Therefore, when only the defect D1 exists on the conductive trace between the S/D terminal SD1 and the word line WL3, the word line driver 211 can still be operated properly in the read operation.

FIG. 10 is a schematic diagram of the word line driver 211 according to other embodiments of the present disclosure. As illustrated in FIG. 10, a defect D2 is located on a conductive trace between the S/D terminal SD3 and the word line WL3.

In some embodiments, similarly to the defect D1 shown in FIG. 9, the defect D2 is an oxide residual which increases the resistance of the conductive trace between the S/D terminal SD3 and the word line WL3.

When a read operation is performed to assert the word line WL2 high, the word line WL3 is asserted low. The main word line signal SM and the reset signal SR are set to a voltage representing digital “1” to turn on the pull-down transistors TD1 and TD2, so as to pull the word line WL3 down to the second voltage VN. However, the resistance of the conductive trace between the S/D terminal SD3 and the word line WL3 increases due to the defect D2, the voltage on the word line WL3 is pulled down to approach but not be equal to the second voltage VN.

In this condition, the pull-down transistor TD1 can still pull the word line WL3 down to the second voltage VN. Therefore, when only the defect D2 exists on the conductive trace between the S/D terminal SD3 and the word line WL3, the word line driver 211 can still be operated properly in the read operation.

FIG. 11 is a schematic diagram of the word line driver 211 according to alternative embodiments of the present disclosure. As illustrated in FIG. 11, the defect D1 is located on the conductive trace between the S/D terminal SD1 and the word line WL3, and the defect D2 is located on the conductive trace between the S/D terminal SD3 and the word line WL3.

Similar to the embodiments shown in FIG. 9 and FIG. 10, the defect D1 is an oxide residual which increases the resistance of the conductive trace between the S/D terminal SD1 and the word line WL3, and the defect D2 is an oxide residual which increases the resistance of the conductive trace between the S/D terminal SD3 and the word line WL3.

When a read operation is performed to assert the word line WL2 high, the word line WL3 is asserted low. The main word line signal SM and the reset signal SR are set to a voltage representing digital “1” to turn on the pull-down transistors TD1 and TD2, so as to pull the word line WL3 down to the second voltage VN. However, the resistance of the conductive trace between the S/D terminal SD1 and the word line WL3 increases due to the defect D1, and the resistance of the conductive trace between the S/D terminal SD3 and the word line WL3 increases due to the defect D2. Therefore, the voltage on the word line WL3 is not pulled down to the second voltage VN. Instead, the voltage on the word line WL3 is higher than the second voltage VN.

In this condition, the word line WL3 is not asserted low to a desired level (i.e., the second voltage VN). Hence, the memory cells M13-M43 are partially turned on, and the charge stored in the memory cells M13-M43 is shared to the bit lines BL1-BL4, respectively. Consequently, the data read in the read operation may be deviated from the real value due to the charge sharing.

FIG. 12 is a schematic diagram of the word line driver 211 according to various embodiments of the present disclosure. As illustrated in FIG. 12, a defect D3 is located on the conductive trace of the main word line MWL between the word line driver 211 and the row decoder 230.

In some embodiments, the defect D3 is an oxide residual which increases the resistance of the conductive trace of the main word line MWL.

When a read operation is performed to assert the word line WL2 high, the word line WL3 is asserted low. The main word line signal SM and the reset signal SR are set to a voltage representing digital “1” to turn on the pull-down transistors TD1 and TD2, so as to pull the word line WL3 down to the second voltage VN. However, the resistance of the conductive trace on the main word line MWL increases due to the defect D3, which causes that the voltage of the main word line signal SM drops when the main word line signal SM reaches the gate terminals G1 and G3. Therefore, in some embodiments, the voltage on the gate terminals Gland G3 is not high enough to turn off the pull-up transistor TU and to turn on the pull-down transistor TD1 completely.

In this condition, the word line WL3 is not asserted low to a desired level (i.e., the second voltage VN). Instead, the voltage on the word line WL3 is between the first voltage VP and the second voltage VN. Hence, the memory cells M13-M43 are partially turned on, and the charge stored in the memory cells M13-M43 is shared to the bit lines BL1-BL4, respectively. Consequently, the data read in the read operation may be deviated from the real value due to the charge sharing.

In order to inspect whether a defect like the defect D1, the defect D2, and/or the defect D3 exists in the memory device 200, a defect inspecting method 20 is provided in the present disclosure to inspect the memory device 200.

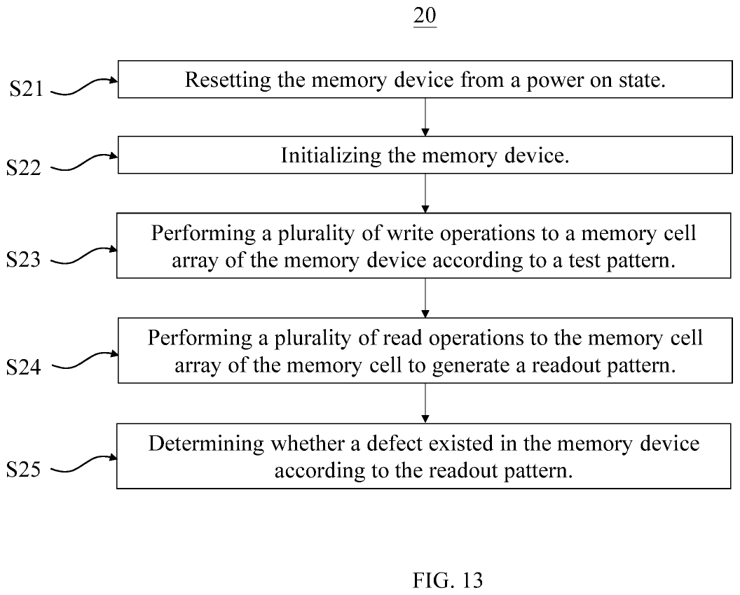

Reference is made to FIG. 13. FIG. 13 is a flow chart of the defect inspecting method 20 according to some embodiments of the present disclosure. In some embodiments, the defect inspecting method 20 is performed by the test device 100 shown in FIG. 1. The defect inspecting method 20 includes operations S21, S22, S23, S24, and S25. To facilitate understanding, the defect inspecting method 20 is described with the numerals shown in FIG. 1 to FIG. 12.

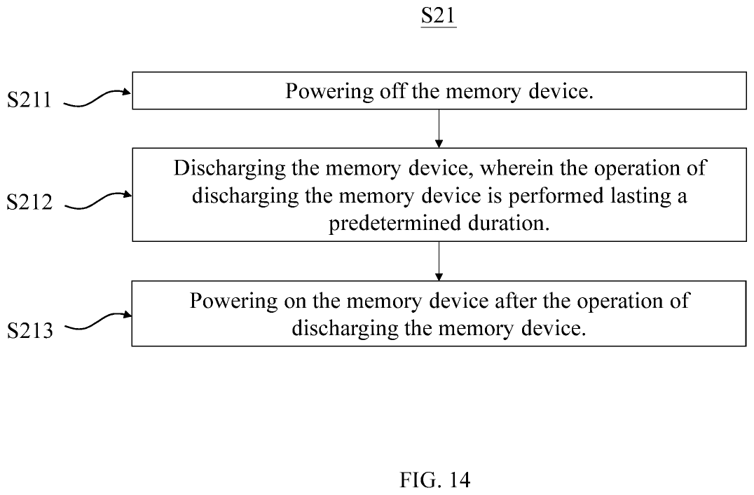

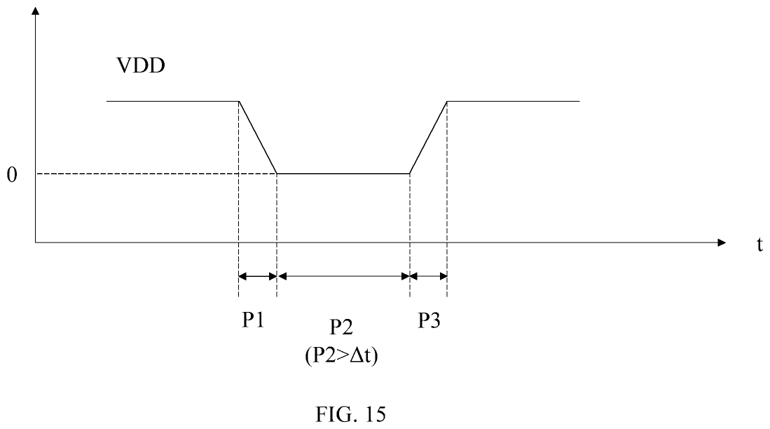

In operation S21, the memory device 200 is reset from a power on state. Please refer to FIG. 14 and FIG. 15. FIG. 14 is a flow chart of the operation S21 according to some embodiments of the present disclosure. FIG. 15 is a schematic diagram of a wave form of a supply power VDD of the memory device 200 according to some embodiments of the present disclosure.

The operation S21 includes operations S211, S212, and S213. In some embodiments, the operations S211, S212, and S213 correspond to periods P1, P2, and P3 in the wave form shown in FIG. 15.

In operation S211, the memory device 200 is powered off from the power on state to a power off state. The supply power VDD is switched to 0 in the operation S211. In some embodiments, a terminal of the memory device 200 receiving the supply power VDD is coupled to the ground in operation S211.

In operation S212, the memory device 200 is discharged, and the terminal of the memory device 200 receiving the supply power VDD is maintained to couple to the ground in the period P2. The period P2 lasts at least longer than a predetermined duration At. In some embodiment, the predetermined duration At is longer than 1 second. In other words, the memory device 200 is discharged at the power off state at least longer than 1 second. In the period P2, the charge resides in the memory device 200 is discharged to the ground. For example, the charge in the parasitic capacitor of the memory device 200 is discharged in the period P2. More particularly, the charge resides around the word line driver 221 (such as the main word line MWL, the word line WL3, the SD terminal SD1, the SD terminal SD3, the gate terminal G1, or the combinations thereof) is discharged in operation S212.

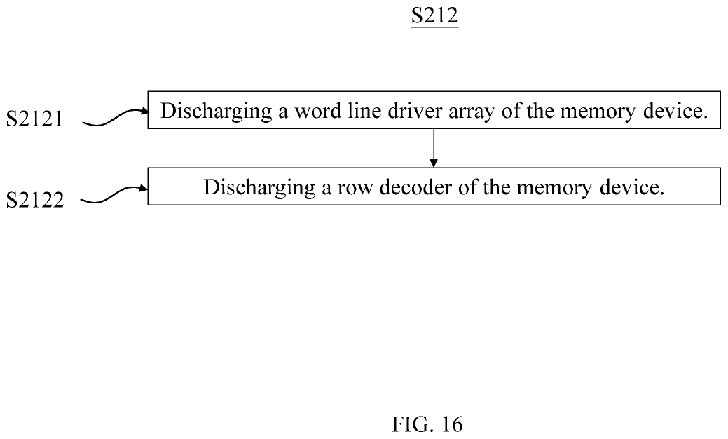

In some embodiments, the operation S212 includes operations S2121 and S2122 as shown in FIG. 16. In operation S2121, the word line driver 221 is discharged. In operation S2122, the row decoder 230 is discharged. The main word line MWL couples the row decoder 230 and the word line driver 221. In some embodiments, when the row decoder 230 and the word line driver 221 are discharged, the charge residual on the main word line MWL is discharged.

In operation S213, the memory device 200 is powered on from the power off state to the power on state.

After the operations S211-S213, the memory device 200 returns to the power on state without charge residual therein.

Please refer back to FIG. 13. In operation S22, the memory device 200 is initialized. In some embodiments, the operations S22 includes but not limit to: providing the external signal to the memory device 200; defining the internal setting of the memory device 200; and calibrating the impedance and timing. In some embodiments, the external signal is a clock signal and/or a reset signal. In some embodiments, the internal setting is Mode Resister Set. In some embodiments, the impedance is about 240 ohm. Specifically, the operation S22 is configured to prepare the memory device 200 to be read and written.

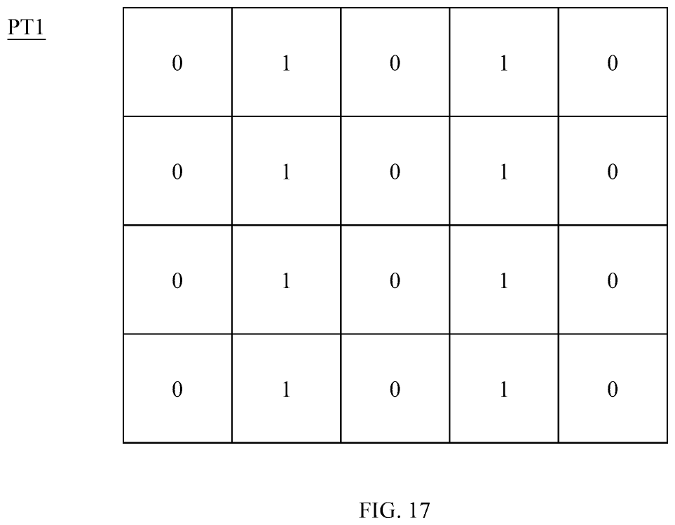

In operation S23, a plurality of write operations are performed to the memory array 211 of the memory device 200 according to a test pattern PT1. The test pattern PT1, as shown in FIG. 17, corresponds to the memory cell array 211. More specifically, the test pattern TP1 indicates a plurality of logic states being written in the memory cells M11-M45 of the memory array 211.

In some embodiments, the test pattern PT1 indicates that the memory cells M11-M41, M13-M43, and M15-M45 are written to store digital “0”, and indicates that the memory cells M12-M42 and M14-M44 are written to store digital “1”. In other words, the memory cells Mij coupled to the word lines WL1, WL3, and WL5 are written to store digital “0”, and the memory cells Mij coupled to the word lines WL2 and WL4 are written to store digital “1”. The test pattern PT1 is provided for illustrative purposes. Various test patterns PT1 are within the contemplated scope of the present disclosure. For example, in various embodiments, the memory cells Mij coupled to the word lines WL1, WL3, and WL5 are written to store digital “1”, and the memory cells Mij coupled to the word lines WL2 and WL4 are written to store digital “0”.

In operation S24, a plurality of read operations are performed to the memory array 211 of the memory device 200 to generate a readout pattern PT2. The readout pattern PT2 corresponds to the memory cell array 211. More specifically, the readout pattern PT2 indicates a plurality of logic states read from the memory cells M11-M45 of the memory array 211.

In operation S25, the test device 100 determines whether a defect existed in the memory device 200 according to the readout pattern PT2. More specifically, the test device 100 compares the test pattern PT1 to the readout pattern PT2.

In some embodiments, the operation S25 includes an operation of respectively comparing the plurality of logic states of the test pattern PT1 to the plurality of logic states of the readout pattern PT2.

When at least one of the plurality of logic states of the readout pattern PT2 is different from the corresponded logic state of the test pattern PT1, a defect is determined existing in the memory device 200. Furthermore, when the defect exists in the memory device 200, the test device 100 is configured to tag the memory device 200 as a fail device. In contrast, when the test device 100 determines that there is no defect existed in the memory device 200, the test device 100 is configured to tag the memory device 200 as a pass device.

In some embodiments, the test device 100 is configured to determine whether a defect existed on the main word line MWL. In some embodiments, the test device 100 is configured to determine whether a defect existed between the sub word line (i.e., word lines WL1-WL5) and the S/D terminal SD1. In some embodiments, the test device 100 is configured to determine whether a defect existed between the sub word line and the S/D terminal SD3.

In some conventional approaches, the DRAM is tested with charge residual in the DRAM. Therefore, the word line may obtain the charge residual in the DRAM to be asserted high enough in the test, so as to completely turn on or turn off the transistors which are coupled to the said word line. Consequently, when a defect causes the resistance of the word line increased, the voltage drop on the word line might not occur while reading the data in the DRAM. The defect is thus not able be detected.

Compared to the above conventional approaches, in the present disclosure, the test device 100 discharges the memory device 200 before inspecting the memory device 200. Because the discharging lasts at least longer than the predetermined duration, the charge residual is discharged without residing in the memory device 200. Therefore, when a defect exists in the memory device 200 and affects the resistance of the word line, the defect also affects the readout pattern PT2 so as to make the readout pattern PT2 different from the test pattern PT1. As a result, when the test device 100 performs the defect inspecting method 20, the defect can be detected by comparing the readout pattern PT2 to the test pattern PT1.

One aspect of the present disclosure provides a defect inspecting method configured to inspect a memory device. The defect inspecting method includes the operations of: resetting the memory device from a power on state; initializing the memory device; performing a plurality of write operations to a memory cell array of the memory device according to a test pattern; performing a plurality of read operations to the memory cell array of the memory cell to generate a readout pattern; and determining whether a defect existed in the memory device according to the readout pattern.

Another aspect of the present disclosure provides a defect inspecting system. The defect inspecting system includes a test device configured to: reset the memory device from a power on state to the power on state through a power off state; perform a plurality of read operations to the plurality of memory cells to generate a readout pattern; and determine whether a defect existed in the memory device according to a readout pattern. The memory device is a Dynamic Random Access Memory (DRAM) device.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, and steps.

What is claimed is:

1. A defect inspecting method for a memory device, comprising:
resetting the memory device from a power on state;
initializing the memory device;
performing a plurality of write operations to a memory cell array of the memory device according to a test pattern;
performing a plurality of read operations to the memory cell array of the memory cell to generate a readout pattern; and
determining whether a defect existed in the memory device according to the readout pattern.

2. The defect inspecting method of claim 1, wherein resetting the memory device from the power on state comprises:
powering off the memory device;
discharging the memory device, wherein the operation of discharging the memory device is performed lasting a predetermined duration; and
powering on the memory device after the operation of discharging the memory device.

3. The defect inspecting method of claim 2, wherein the predetermined duration is longer than 1 second.

4. The defect inspecting method of claim 2, wherein discharging the memory device comprises:
discharging a word line driver array of the memory device; and
discharging a row decoder of the memory device.

5. The defect inspecting method of claim 1, wherein the test pattern indicates a plurality of first logic states being written in a plurality of memory cells of the memory array, respectively, and the readout pattern indicates a plurality of second logic states read from the plurality of memory cells of the memory array, respectively.

6. The defect inspecting method of claim 5, wherein determining whether the defect existed in the memory device according to the readout pattern comprises:
comparing the plurality of the first logic states to the plurality of the second logic states,
wherein when at least one of the plurality of second logic states is different from the corresponded first logic state, the defect is determined existing in the memory device.

7. The defect inspecting method of claim 1, wherein the memory device comprises a row decoder and a word line driver array coupled to the row decoder through a main word line, wherein the operation of determining whether the defect existed in the memory device according to the readout pattern is configured to detect whether the defect existed on the main word line.

8. The defect inspecting method of claim 7, wherein the word line driver array comprises a plurality of word line drivers, wherein at least one of the word line drivers comprises:
a first pull-down transistor having a first gate terminal, a first source/drain (S/D) terminal, and a second S/D terminal;
a second pull-down transistor having a second gate terminal, a third S/D terminal, and a fourth S/D terminal; and
a pull-up transistor having a third gate terminal, a fifth S/D terminal, and a sixth S/D terminal,
wherein the first gate terminal and the third gate terminal are configured to receive a main word line signal, the second gate terminal is configured to receive a reset signal, the firs S/D terminal, the third S/D terminal, and the sixth S/D terminal are coupled to a sub word line, the fifth S/D terminal is configured to receive a first voltage, and the second S/D terminal and the fourth S/D terminal are configured to receive a second voltage,
wherein the operation of determining whether the defect existed in the memory device according to the readout pattern is further configured to detect whether the defect existed between the sub word line and the first S/D terminal.

9. The defect inspecting method of claim 8, wherein the operation of determining whether the defect existed in the memory device according to the readout pattern is further configured to detect whether the defect existed between the sub word line and the third S/D terminal.

10. The defect inspecting method of claim 7, wherein the defect increases a resistance of the main word line.

11. A defect inspecting system for a memory device, comprising:
a test device, configured to:
reset the memory device from a power on state to the power on state through a power off state;
perform a plurality of read operations to the plurality of memory cells to generate a readout pattern; and
determine whether a defect existed in the memory device according to a readout pattern,
wherein the memory device is a Dynamic Random Access Memory (DRAM) device.

12. The defect inspecting system of claim 11, wherein the test device is further configured to:
initialize the memory device; and
perform a plurality of write operations to a plurality of memory cells of the memory device according to a test pattern.

13. The defect inspecting system of claim 12, wherein the test device determines whether the defect existed in the memory device according to the readout pattern by:
comparing the readout pattern to the test pattern, wherein the test pattern indicates a plurality of first logic states being written in the memory device, and the readout pattern indicates a plurality of second logic states read from the memory device,
wherein when at least one of the plurality of the second logic states is different from the corresponded first logic state, the test device determines the defect existed in the memory device.

14. The defect inspecting system of claim 11, wherein the test device resets the memory device by:
powering off the memory device to the power off state;
discharging the memory device for a predetermined duration in the power off state; and
powering on the memory device to the power on state.

15. The defect inspecting system of claim 14, wherein the predetermined duration is longer than 1 second.

16. The defect inspecting system of claim 14, wherein the memory device comprises:
a memory array comprising a plurality of memory cells;
a row decoder configured to provide a main word line signal through a main word line; and
a word line driver array configured to receive the main word line signal, wherein the word line driver array comprises a plurality of word line drivers, and at least one of the word line drivers is configured to generate a sub word line signal to the memory array,
wherein the test device is configured to discharge the main word line.

17. The defect inspecting system of claim 16, wherein the test device is configured to determine whether the defect existed on the main word line, wherein the defect is caused by an oxide residual.

18. The defect inspecting system of claim 16, wherein at least one of the word liner drivers comprises:
a first pull-down transistor having a first gate terminal, a first source/drain (S/D) terminal, and a second S/D terminal;
a second pull-down transistor having a second gate terminal, a third S/D terminal, and a fourth S/D terminal; and
a pull-up transistor having a third gate terminal, a fifth S/D terminal, and a sixth S/D terminal,
wherein the first gate terminal and the third gate terminal are configured to receive the main word line signal, the second gate terminal is configured to receive the reset signal, the firs S/D terminal, the third S/D terminal, and the sixth S/D terminal are coupled to a sub word line, the fifth S/D terminal is configured to receive a first voltage, and the second S/D terminal and the fourth S/D terminal are configured to receive a second voltage,
wherein the test device is configured to discharge the word line driver.

19. The defect inspecting system of claim 18, wherein the test device is configured to determine whether the defect existed between the sub word line and the first S/D terminal, and/or between the sub word line and the third S/D terminal.

20. The method of claim 11, wherein the test device is configured to tag the memory device as a fail device when the defect exists in the memory device.
